(19) United States
(12) Patent Application Publication
(10) Pub. No.: US 2025/0248138 A1
(43) Pub. Date: Jul. 31, 2025

(54) HIGH EFFICIENCY SINGLE-PHOTON AVALANCHE DIODE (SPAD) PIXEL

(71) Applicant: Samsung Electronics Co., Ltd., Suwon-si (KR)

(72) Inventors: Tze Ching Fung, Diamond Bar, CA (US); Radwanul Hasan Siddique, Monrovia, CA (US); Yibing Michelle Wang, Temple City, CA (US)

(21) Appl. No.: 18/642,368

(22) Filed: Apr. 22, 2024

Related U.S. Application Data
(60) Provisional application No. 63/626,159, filed on Jan. 29, 2024.

(51) Int. Cl. H01L 31/107; H01L 21/762; H01L 31/0232

(52) U.S. Cl. CPC H10F 30/225; H01L 21/76224; H10F 77/413

(57) ABSTRACT

A photodetector includes photo-sensing elements, micro-lens on the photo-sensing elements, and a refractive element between one of the photo-sensing elements and one of the micro-lens. The refractive element may be a multi-facet prism, a Fresnel prism, or a nanostructure prism. The photo-sensing elements may be single-photon avalanche diodes (SPADs) and/or photodiodes.

### CROSS-REFERENCE TO RELATED APPLICATION(S)

The present application claims priority to and the benefit of U.S. Provisional Application No. 63/626,159, filed Jan. 29, 2024, the entire content of which is incorporated herein by reference.

### BACKGROUND

### 1. Field

Aspects of the present disclosure relate to single-photon avalanche diode (SPAD) pixels and photodiodes.

### 2. Description of the Related Art

Single-photon avalanche diodes (SPADs) are photodetectors that include a junction between a p-type semiconductor material and an n-type semiconductor material. A large reverse bias is applied to the semiconductor p-n junction such that when a photon irradiates the SPAD, impact ionization occurs. This impact ionization causes an avalanche current to develop. In this manner, a SPAD is configured to detect single photons.

SPAD pixels typically include multiple sensing elements and in-pixel logic circuitry. The design of the logic circuitry should comply with design rule constraints and include electrical isolation between the logic circuitry and the sensing elements. However, these design constraints may result in a low SPAD pixel fill factor or it may result in the sensing elements not being designed symmetrically to their center axis. On-chip micro-lenses are commonly utilized to focus the incoming light to a smaller area, thereby increasing the effective fill factor and the photon detection efficiency (PDE) of the SPAD pixel. However, because micro-lenses are typically designed to have a symmetric shape (e.g. circle) around their optical center axis, the focused light by the micro-lenses will not be aligned with the active regions of the sensing elements if the sensing elements cannot be aligned with the optical centers of the micro-lenses, which results in a low PDE. Additionally, some related art SPAD pixels may reduce the size of the micro-lenses or add on-chip prisms to address the misalignment between the micro-lenses and the sensing elements, but this complicates the fabrication process and creates dead spaces in between the sensing elements, which limits the achievable fill factor of the SPAD pixel.

The above information disclosed in this Background section is only for enhancement of understanding of the present disclosure, and therefore it may contain information that does not form the prior art that is already known to a person of ordinary skill in the art.

### SUMMARY

The present disclosure relates to various embodiments of a photodetector. In one embodiment, the photodetector includes a number of pixels and each pixel includes a number of photo-sensing elements, at least one micro-lens on the photo-sensing elements, and a refractive element between photo-sensing elements and the micro-lens. An optical center of the micro-lens is offset from a center of each of the sensing elements. Photons passing through the micro-lens are refracted by the refracting element onto the sensing elements.

A number of the micro-lenses may be less than a number of the sensing elements.

The refractive element may include a material having a refractive index greater than 1.5.

The material of the refractive element may include one or multiple high index materials such as SiO₂, Si₃N₄, Si, Ge, GaN, GaAs, InAs, InP, ZnS, ZnSe, ZnTe, PbTe, PbSe, PbS, Te, HfO₂, TiO₂, ZrO₂, Al₂O₃, Ta₂O₅, LiNbO₃ or high refractive index polymer material.

The refractive element may be a multi-facet prism.

The refractive element may be a Fresnel prism.

The refractive element may be a nanostructure meta prism.

A number of facets of the multi-facet prism may be equal to a number of sensing elements in the pixel.

Facets of the multi-facet prism may be angled at one or more different angles.

An angle of a first facet of the multi-facet prism may be substantially zero.

The photo-sensing elements may be single-photon avalanche diodes (SPADs).

The photo-sensing elements may be photodiodes.

The present disclosure also relates to various embodiments of a pixel architecture. In one embodiment, the pixel architecture includes an array of photo-sensing elements each including an anode and a cathode shared between adjacent photo-sensing elements. The pixel architecture also includes CMOS elements between the array of photo-sensing elements. Each of the CMOS elements includes a p-well and an n-well. The pixel architecture further includes micro-lenses on the array of photo-sensing elements, and at least one isolation structure separating at least one of the photo-sensing elements from at least one of the CMOS elements.

Each of the micro-lenses may be substantially symmetric and optical centers of the micro-lenses may be substantially aligned with centers of the photo-sensing elements.

The at least one isolation structure may include a shallow-trench isolation and an ISO implant.

The shallow-trench isolation may also include a backside trench isolation (BTI).

The isolation structure may include a backside trench isolation contacting a shallow-trench isolation.

The at least one isolation structure may surround at least one of the CMOS elements.

This summary is provided to introduce a selection of concepts that are further described below in the detailed description. This summary is not intended to identify key or essential features of the claimed subject matter, nor is it intended to be used in limiting the scope of the claimed subject matter. One or more of the described features may be combined with one or more other described features to provide a workable device.

### BRIEF DESCRIPTION OF THE DRAWINGS

The features and advantages of embodiments of the present disclosure will be better understood by reference to the following detailed description when considered in conjunction with the drawings. The drawings are not necessarily drawn to scale.

FIGS. 1A-1B are a top view and a cross-sectional view, respectively, of a photodetector according to one embodiment of the present disclosure including a sensing element, a micro-lens, and a refractive element between the sensing element and the micro-lens. a related art micro-lens design is also shown in FIG. 1A for comparison;

FIGS. 2A-2B are a top view and a cross-sectional view, respectively, of a multi-facet prism as the refractive element of the photodetector of FIGS. 1A-1B according to one embodiment of the present disclosure, wherein circular dots in FIG. 2A illustrate the focus light spots relative to the sensing elements of the pixel;

FIGS. 3A-3B are a top view and a cross-sectional view, respectively, of a Fresnel lens as the refractive element of the photodetector of FIGS. 1A-1B according to one embodiment of the present disclosure;

FIGS. 4A-4B are a top view and a cross-sectional view, respectively, of a nanostructure lens as the refractive element of the photodetector of FIGS. 1A-1B according to one embodiment of the present disclosure;

FIGS. 5A-5B are a top view and a cross-sectional view, respectively, of multi-facet prism as the refractive element of the photodetector of FIGS. 1A-1B according to another embodiment of the present disclosure, wherein circular dots in FIG. 5A illustrate the focus light spots relative to the sensing elements of the pixel;

FIGS. 6A-6B are a top view and a cross-sectional view, respectively, Fresnel as the refractive element of the photodetector of FIGS. 1A-1B according to one embodiment of the present disclosure;

FIGS. 7A-7B are a top view and a cross-sectional view, respectively, of a nanostructure lens as the refractive element of the photodetector of FIGS. 1A-1B according to one embodiment of the present disclosure;

FIGS. 8A-8B are a top view and a cross-sectional view, respectively, of a photodetector according to another embodiment of the present disclosure;

FIGS. 9A-9C are a top view and first and second cross-sectional views, respectively, of a photodetector according to one embodiment of the present disclosure; and

FIGS. 10A-10C are a top view and first and second cross-sectional views, respectively, of a photodetector according to one embodiment of the present disclosure.

### DETAILED DESCRIPTION

The present disclosure relates to various embodiments of a photodetector, such as a single-photon avalanche diode (SPAD) pixel or a photodiode (PD) pixel. In one or more embodiments, the pixel includes at least one sensing element, a micro-lens, and a refractive element between the sensing element and the micro-lens that is configured to refract photons passing through the micro-lens onto the sensing element. For instance, in one or more embodiments in which the optical center of the micro-lens is not aligned with the sensing element, the refractive element is configured to redirect the incoming photons onto the sensing element. In this manner, the refractive element may increase the effective fill factor (FF) (i.e., the ratio of the optically sensitive area to the total area of the pixel) and the photon detection efficiency (PDE) of the photodetector. As used herein, the effective fill factor (FF) is the ratio of the optically sensitive area to the total pixel area. For instance, if there is no micro-lens or other refractive element, the optically sensitive area is just the sensing element (or anode) and thus the FF is quite low, such as less than 50%. In an embodiment with a micro-lens, the optically sensitive area enlarges to the area of the micro-lens and thus the FF increases compared to the case without the micro-lens. In an embodiment including a refractive element, discussed in detail below, the micro-lens can be designed to be much larger and thereby significantly increase the FF. The present disclosure also relates to various embodiments of a photodetector in which adjacent sensing elements share a cathode (i.e., a common cathode). In one or more embodiments, the photodetector includes CMOS elements (including N-well (PMOS) and p-well (NMOS) elements) between the photo sensing elements. Although in the figures the p-type and the n-type semiconductor regions are shown in a particular configuration, in one or more embodiments the p-type and the n-type semiconductor regions may be swapped (interchanged) and the polarity of the isolation region may be altered accordingly. In one or more embodiments, the photodetector may include an isolation structure to prevent (or at least mitigate against) current leakage between SPAD cathodes and transistor wells.

Hereinafter, example embodiments will be described in more detail with reference to the accompanying drawings, in which like reference numbers refer to like elements throughout. The present invention, however, may be embodied in various different forms, and should not be construed as being limited to only the illustrated embodiments herein. Rather, these embodiments are provided as examples so that this disclosure will be thorough and complete, and will fully convey the aspects and features of the present invention to those skilled in the art. Accordingly, processes, elements, and techniques that are not necessary to those having ordinary skill in the art for a complete understanding of the aspects and features of the present invention may not be described. Unless otherwise noted, like reference numerals denote like elements throughout the attached drawings and the written description, and thus, descriptions thereof may not be repeated.

In the drawings, the relative sizes of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present invention.

The terminology used herein is for the purpose of describing particular embodiments and is not intended to be limiting of the present invention. As used herein, the singular forms “a” and “an” are intended to include the plural forms as well, unless the context clearly indicates otherwise. It will be further understood that the terms “comprises,” “comprising,” “includes,” and “including,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. Expressions such as “at least one of,” when preceding a list of elements, modify the entire list of elements and do not modify the individual elements of the list.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present invention refers to “one or more embodiments of the present invention.” As used herein, the terms “use,” “using,” and “used” may be considered synonymous with the terms “utilize,” “utilizing,” and “utilized,” respectively. Also, the term “exemplary” is intended to refer to an example or illustration.

Unless otherwise defined, all terms (including technical and scientific terms) used herein have the same meaning as commonly understood by one of ordinary skill in the art to which the present invention belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

For the purposes of this disclosure, expressions such as “at least one of,” when preceding a list of elements, modify the entire list of elements and do not modify the individual elements of the list. For example, “at least one of X, Y, and Z,” “at least one of X, Y, or Z,” and “at least one selected from the group consisting of X, Y, and Z” may be construed as X only, Y only, Z only, any combination of two or more of X, Y, and Z, such as, for instance, XYZ, XYY, YZ, and ZZ, or any variation thereof. Similarly, the expression such as “at least one of A and B” may include A, B, or A and B. As used herein, “or” generally means “and/or,” and the term “and/or” includes any and all combinations of one or more of the associated listed items. For example, the expression such as “A and/or B” may include A, B, or A and B.

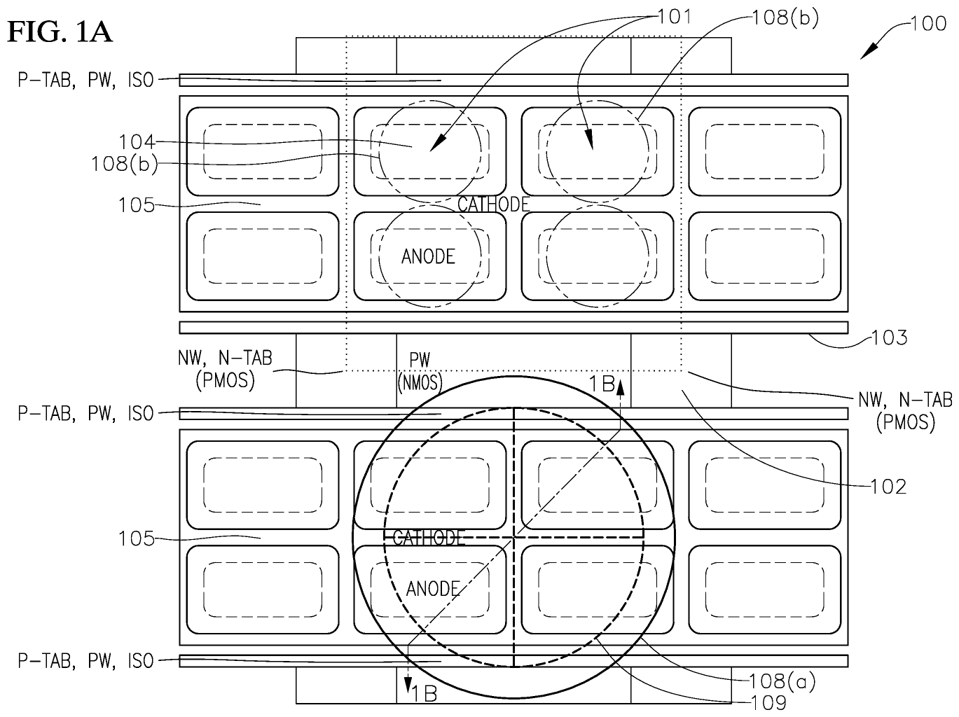

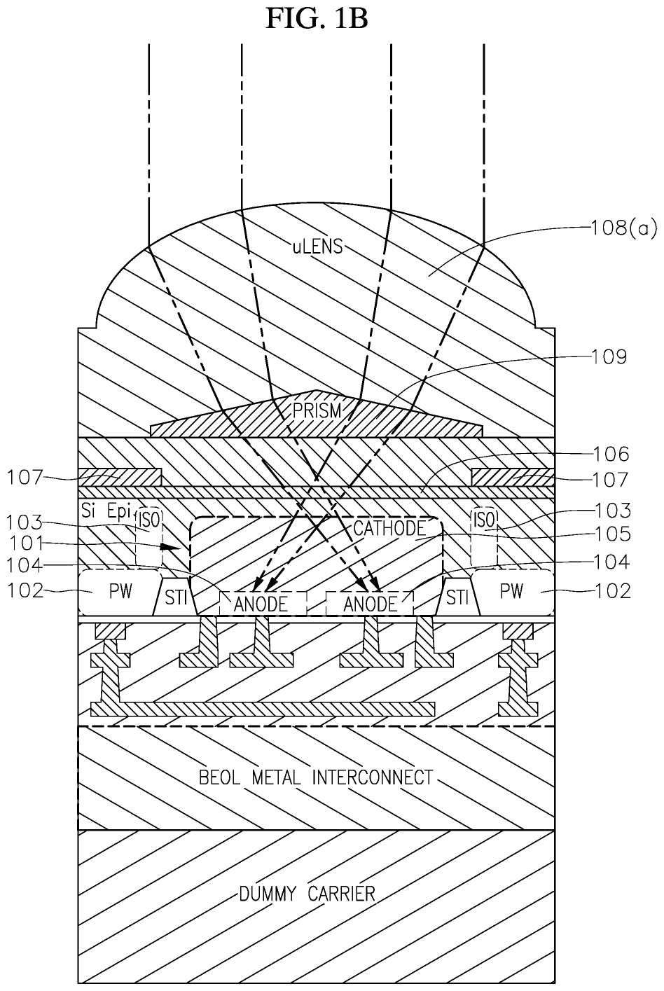

With reference now to FIGS. 1A-1B, a photodetector 100 according to one embodiment of the present disclosure includes an array of pixels containing sensing elements 101 and pixel logic circuitry 102 (e.g., a CMOS pixel circuit) electrically isolated from the array of sensing elements 101 by an isolation region 103 (e.g., a deep p-type implant region). In the illustrated embodiment, the sensing elements 101 are arranged in a grid of rows and columns. Additionally, in the illustrated embodiment, each pixel contains four sensing elements 101 arranged in a 2×2 square grid. A pixel maybe further divided into four equal-sized quadrants and each quadrant contains one sensing element. The sensing elements 101 may be single-photon avalanche diodes (SPADs) and/or photodiodes (PDs). In the illustrated embodiment, each of the sensing elements 101 is a back-side illuminated SPAD pixel including an anode 104 and a cathode 105 on the anode 104 (e.g., the array of sensing elements 101 includes an array or grid of anodes 104 and a common cathode 105 on the anodes 104). The anode 104 is formed of a p-type semiconductor material, and the cathode 105 is formed of an n-type semiconductor material. Together, the anodes 104 and the cathode 105 form semiconductor p-n junctions. A reverse bias is applied to the sensing elements 101 by connecting the n-type semiconductor region to the positive terminal (cathode) of a power supply and connecting the p-type semiconductor regions to the negative terminal (anode) of the power supply. In one or more embodiments in which the sensing elements 101 are photodiodes, the reverse bias may be relatively low. In one or more embodiments in which the sensing elements 101 are SPADs, the reverse bias may be relatively high (e.g., the reverse bias may be sufficiently high such that impact ionization occurs when photons irradiate the sensing elements 101, which causes an avalanche current to develop).

In the illustrated embodiment, the photodetector 100 also includes at least one dielectric layer (or dielectric stack) 106 on the array of sensing elements 101, and light shielding elements 107 on the dielectric layer 106. The light shielding elements 107 cover the logic circuitry 102 and expose the array of sensing elements 101.

In the illustrated embodiment, the photodetector 100 also includes an array of micro-lenses 108 on the dielectric layer 106. The upper portion of FIG. 1A depicts a related art photodetector 100 including relatively small micro-lenses 108(b) and the lower portion of FIG. 1A depicts the photodetector 100 according to one embodiment of the present disclosure with relatively large micro-lenses 108(a). As shown in FIG. 1A, the micro-lenses 108(a) according to one or more embodiments of the present application are larger than the micro-lenses 108(b) of the related art, which increases the FF of the photodetector 100 of the present application compared to the related art configuration. The number of micro-lenses 108 may be the same as or less than the number of sensing elements 101 in the pixel. The micro-lenses 108 are configured to direct photons (e.g., ultraviolet (UV) light, visible light, and/or infrared (IR)) toward the sensing elements 101. Additionally, in one or more embodiments, the micro-lenses 108 may be symmetric (or substantially symmetric) about their optical center axis, the sensing elements 101 may not be symmetric about their centers (e.g., the sensing elements may be rectangular) and each sensing element 101 may not align with the geometrical center of corresponding pixel quadrant. In the related art, micro-lenses 108(b) are designed to be small so they can be aligned with the centers of the sensing elements 101. However, in such approach the micro-lenses only occupied a relatively small area in the entire pixel. In the present disclosure, with the refractive element 109, the optical center axes of the micro-lens 108(a) may not be aligned with the centers of the sensing elements 101, but aligned with the center of the entire pixel instead (e.g., the optical center of micro-lens 108(a) may be offset from the center of the respective sensing elements 101).

In the illustrated embodiment, the photodetector 100 also includes at least one refractive element 109 between the array of sensing elements 101 and the micro-lens 108(a). The refractive element 109 is configured to direct the photons (e.g., ultraviolet (UV) light, visible light, and/or infrared (IR)) that have passed through one of the micro-lenses 108(a) to the sensing elements 101, which might not otherwise occur due to the misalignment between the micro-lenses 108 and the sensing elements 101. The number of refractive elements 109 may be less than the number of sensing elements 101. In one or more embodiments, the refractive element 109 may have a refractive index of approximately 1.5 or greater. In one or more embodiments, the refractive element 109 may include one or multiple high index materials such as SiO₂, Si₃N₄, Si, Ge, GaN, GaAs, InAs, InP, ZnS, ZnSe, ZnTe, PbTe, PbSe, PbS, Te, HfO₂, TiO₂, ZrO₂, Al₂O₃, Ta₂O₅, LiNbO₃ or high refractive index polymer material.

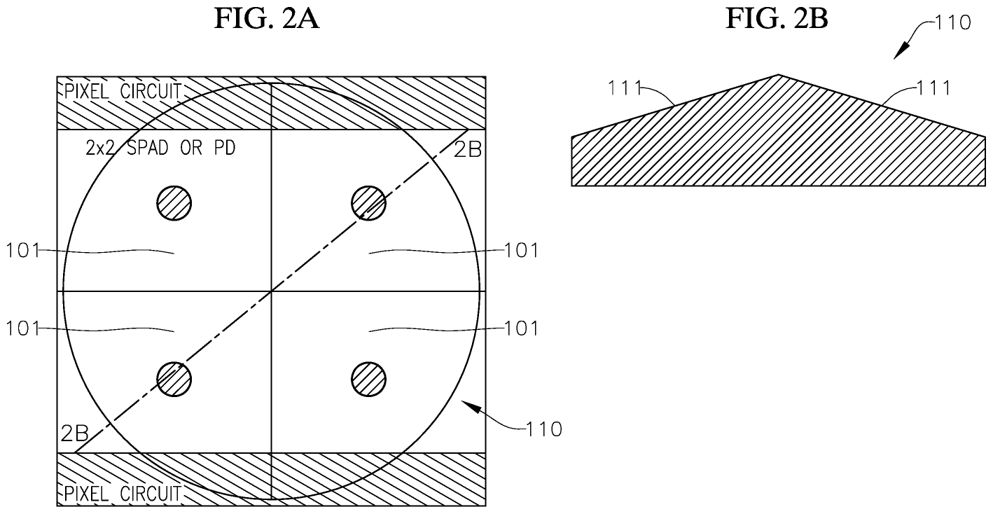

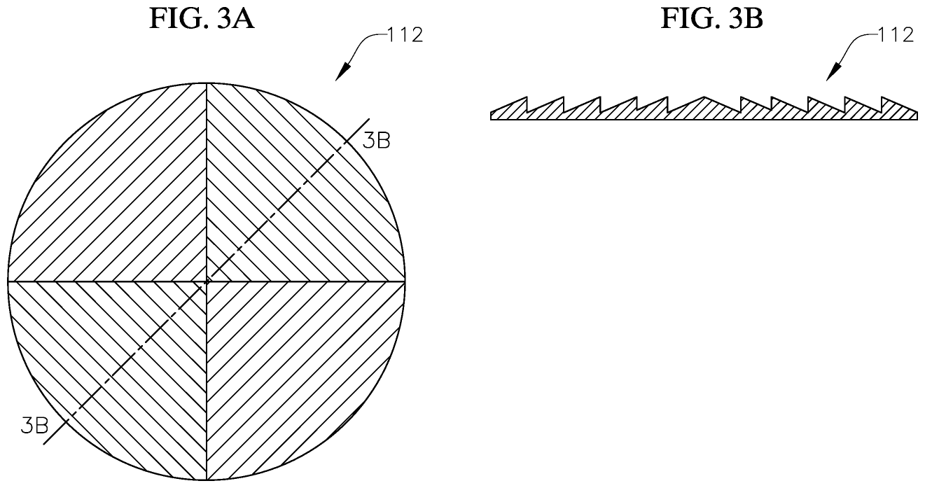

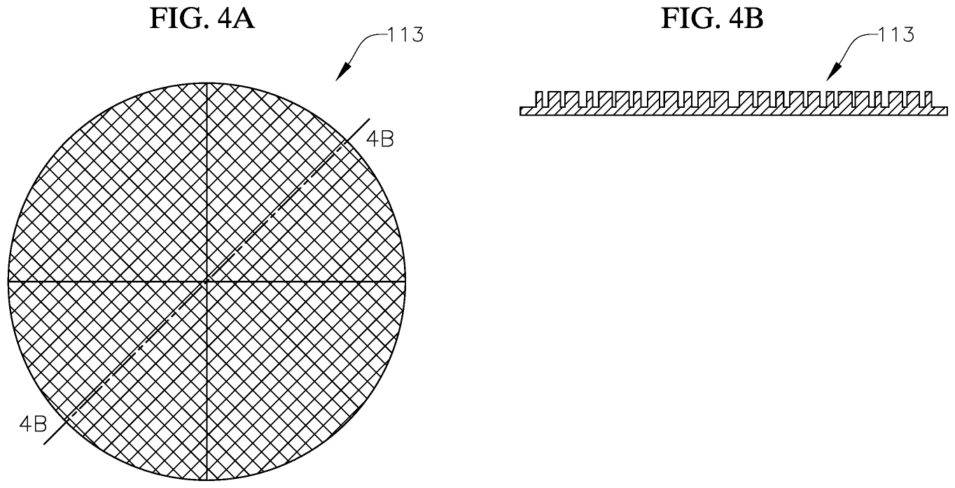

In one or more embodiments, the refractive element 109 may be a multi-facet prism. Each facet of the multi-facet prism may be configured to direct photons to different sensing elements 101. In the embodiment illustrated in FIGS. 2A-2B, the refracting element 109 is a four-facet prism 110 that is configured to direct incident photons onto one of four sensing elements 101 (e.g., SPAD or PD sensing elements) arranged in a 2×2 square grid. The angle of the facets 111 may be configured to direct the incident photons into the center or central area (or substantially the center or central area) of the respective sensing element 101. In the embodiment illustrated in FIGS. 3A-3B, the refracting element 109 may be a Fresnel lens 112 configured to generate the same or substantially the same output wavefront as the four-facet prism 110 illustrated in FIGS. 2A-2B (e.g., the refracting element 109 may be a Fresnel lens 112 configured to direct incident photons onto four sensing elements 101 arranged in a square grid). In the embodiment illustrated in FIGS. 4A-4B, the refracting element 109 may be a nanostructure lens 113 configured to generate the same or substantially the same output wavefront as the four-facet prism 110 illustrated in FIGS. 2A-2B (e.g., the refracting element 109 may be a nanostructure meta prism configured to direct incident photons onto four sensing elements 101 arranged in a square grid).

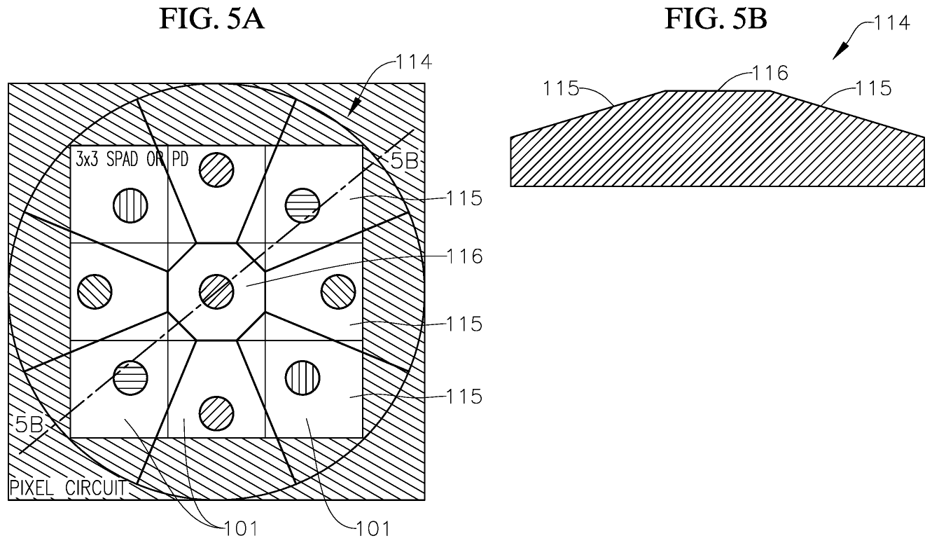

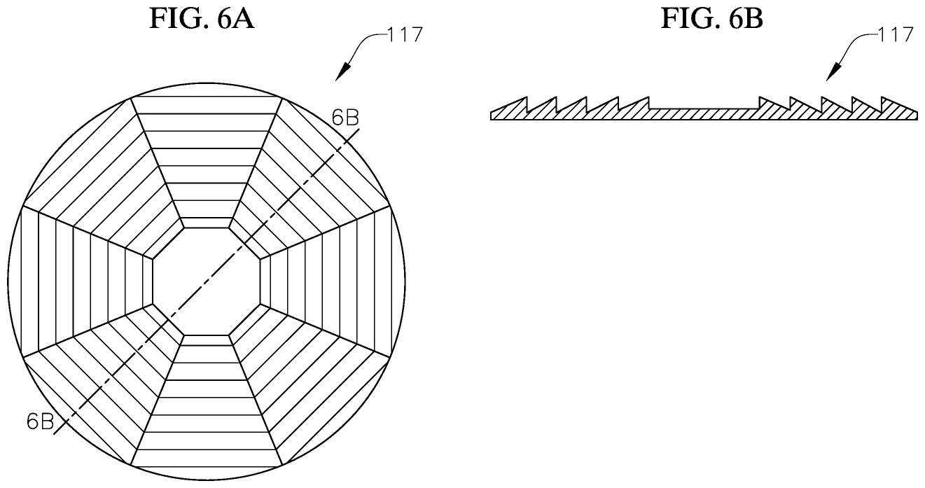

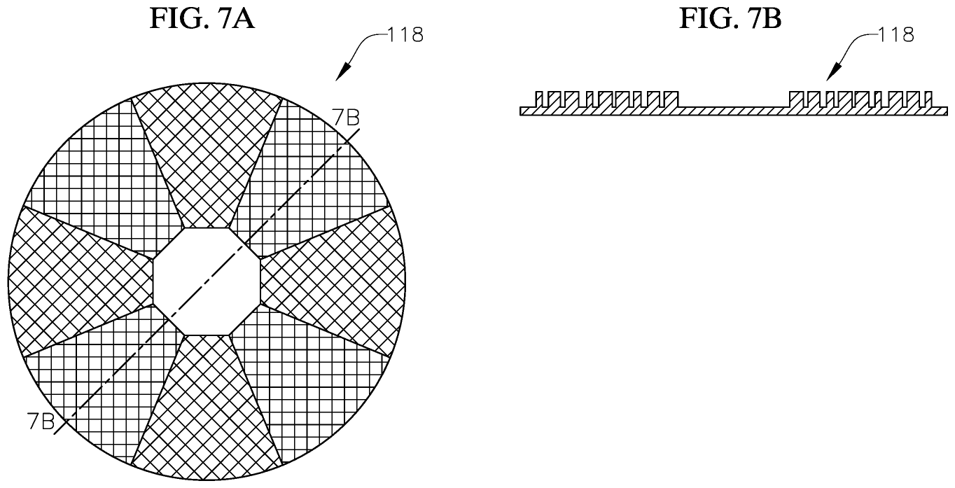

In another embodiment illustrated in FIGS. 5A-5B, each pixel contains nine sensing elements 101 arranged in a 3×3 square grid surrounded by pixel circuitry. A pixel may be fictitiously divided into nine equal-sized sub-regions. Sensing elements 101 may be symmetric about their centers (e.g., the sensing elements may be square) but each sensing element 101 may not align with the geometrical center of corresponding sub-pixel regions. The refracting element 109 is a nine-facet prism 114 that is configured to direct incident photons onto one of nine sensing elements 101 (e.g., SPAD or PD sensing elements) arranged in a 3×3 square grid. The angle of the facets may be configured to direct the incident photons into the center or central area (or substantially the center or central area) of the respective sensing element. In the illustrated embodiment, the nine-facet prism 114 include two different facet angles—a first angle for each of eight facets 115 arranged peripherally on the prism 114, and a second angle for a central facet 116. The second angle may be zero or substantially zero such that the central facet 116 is configured not to refract incident photons (e.g., photons incident on the central facet 116 pass straight through the central facet 116 and arrive at a sensing element 101 that is aligned below the central facet 116 of the prism 114). Although in the illustrated embodiment each of the eight facets 115 arranged around the periphery of the prism 114 have the same or substantially the same angle, in one or more embodiments, these eight facets 115 may have two or more different angles depending, for instance, on the arrangement of the sensing elements 101 below the prism 114. In the embodiment illustrated in FIGS. 6A-6B, the refracting element 109 may be a Fresnel lens 117 configured to generate the same or substantially the same output wavefront as the nine-facet prism 114 illustrated in FIGS. 5A-5B (e.g., the refracting element 109 may be a Fresnel lens 117 configured to direct incident photons onto nine sensing elements 101 arranged in a square grid). In the embodiment illustrated in FIGS. 7A-7B, the refracting element 109 may be a nanostructure lens 118 configured to generate the same or substantially the same output wavefront as the nine-facet prism 114 illustrated in FIGS. 5A-5B (e.g., the refracting element 109 may be a nanostructure meta prism 118 configured to direct incident photons onto nine sensing elements 101 arranged in a square grid).

In operation, photons passing through the micro-lenses 108(a) are refracted by the refracting element 109 (e.g., the multi-facet prism 110 or 114, the equivalent Fresnel lens 112 or 117, or the equivalent nanostructure lens 113 or 118, respectively) onto the sensing elements 101 (e.g., the center or substantially the center of the SPAD or PD sensing elements 101), which would not otherwise occur due to the misalignment between the micro-lens 108(a) and the sensing elements 101. In this manner, micro-lens 108(a) may be designed to occupy a much larger area of pixel than a related art micro-lens (e.g. micro-lens 108(b)), hence the refracting element 109 increases the effective fill factor (FF) and photon detection efficiency (PDE) of the photodetector 100.

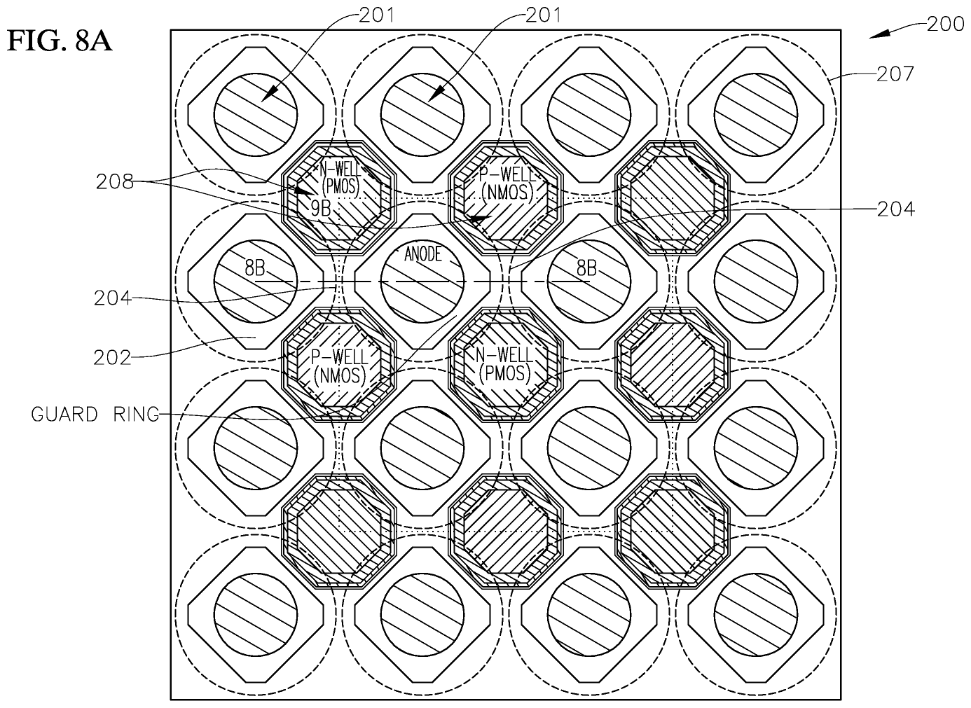

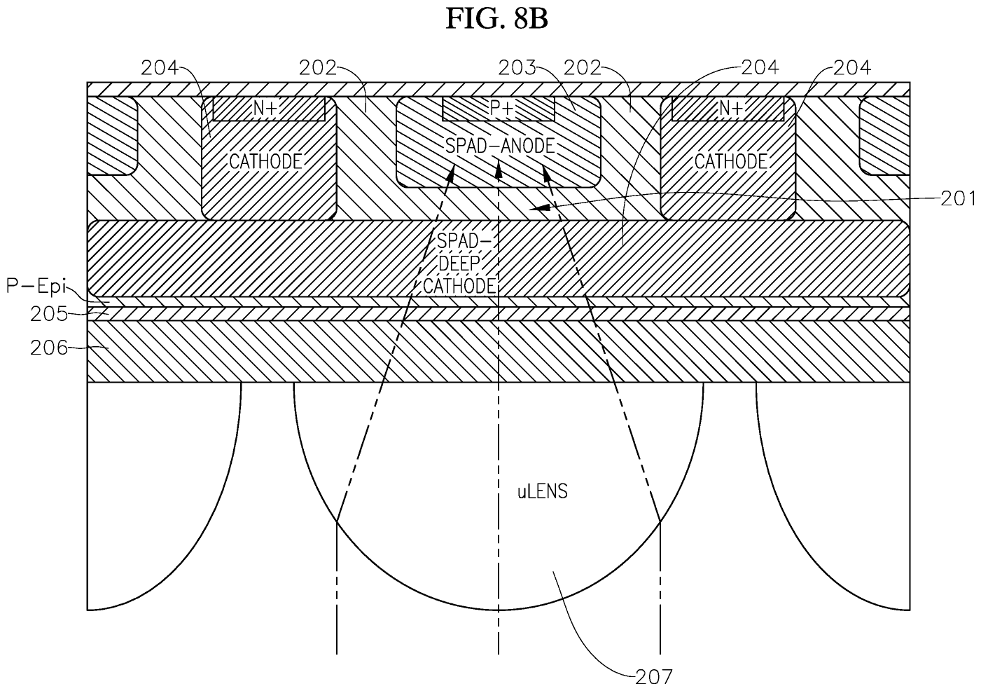

With reference now to FIGS. 8A-8B, a photodetector 200 according to another embodiment of the present disclosure includes an array of sensing elements 201. In the illustrated embodiment, the sensing elements 201 are arranged in a grid of rows and columns. In the illustrated embodiment, each of the sensing elements 201 is surrounded by a guard ring 202 which includes a low electric field region. The sensing elements 201 may be single-photon avalanche diodes (SPADs) and/or photodiodes (PDs). Additionally, in the illustrated embodiment, each of the sensing elements 201 is a back-side illuminated SPAD pixel including an anode 203 and a cathode 204 on the anode 203 (e.g., the array of sensing elements 201 includes an array or grid of anodes 203 and a common cathode 204 on the anodes 203). The anode 203 is formed of a p-type semiconductor material, and the cathode 204 is formed of an n-type semiconductor material. Together, the anodes 203 and the cathode 204 form p-n junctions. A reverse bias is applied to the sensing elements 201 by connecting the n-type semiconductor region to the positive terminal (cathode) of a power supply and connecting the p-type semiconductor regions to the negative terminal (anode) of the power supply. In one or more embodiments in which the sensing elements 201 are photodiodes, the reverse bias may be relatively low. In one or more embodiments in which the sensing elements 201 are SPADs, the reverse bias may be relatively high (e.g., the reverse bias may be sufficiently high such that impact ionization occurs, which enables an avalanche current to develop).

In the illustrated embodiment, adjacent sensing elements 201 (e.g., adjacent SPADs or PDs) share a cathode 204 (i.e., a common cathode 204 is shared between adjacent sensing elements 201). Sharing the cathode 204 between adjacent (or neighboring) sensing elements 201 increases the fill factor (FF) of the photodetector 200.

In the illustrated embodiment, the photodetector 200 also includes a dielectric stack 205 on the array of sensing elements 201, and a planarization layer 206 on the dielectric stack 205.

In the illustrated embodiment, the photodetector 200 includes an array of micro-lenses 207 on the planarization layer 206. The number of micro-lenses 207 may be the same as the number of sensing elements 201 in the array of sensing elements. The micro-lenses 207 are configured to direct photons (e.g., ultraviolet (UV) light, visible light, and/or infrared (IR)) toward the sensing elements 201. Each pixel contains four sensing elements 201 arranged in a 2×2 square grid. A pixel maybe further divided into four equal-sized quadrants and each quadrant contains one sensing element. Additionally, in one or more embodiments, the micro-lenses 207 may be symmetric (or substantially symmetric) about their optical centers, the sensing elements 201 may be symmetric (or substantially symmetric) (e.g., circular), and the optical centers of the micro-lenses 207 may be aligned (or substantially aligned) with the centers of the sensing elements 201, as well as the geometrical centers of the corresponding pixel quadrants.

In the illustrated embodiment, the photodetector 200 also includes pixel circuitries 208 (e.g., CMOS pixel circuits) adjacent or proximate to the sensing elements 201. In the illustrated embodiment, the in-pixel circuitries 208 are within the array of sensing elements 201 (e.g., the in-pixel circuitries 208 are in gaps between the sensing elements 201 in the array). Additionally, in the illustrated embodiment, the in-pixel circuitries 208 are horizontally and vertically offset from the sensing elements 201 (e.g., the in-pixel circuitries 208 and the sensing elements 201 may be staggered). In one or more embodiments, the in-pixel circuitries 208 may be arranged in a grid of rows and columns. For instance, in the illustrated embodiment, a first row of the in-pixel circuitries 208 is between a first row and a second row of the sensing elements 201, and a first column of the in-pixel circuitries 208 is between a first column and a second column of the sensing elements 201.

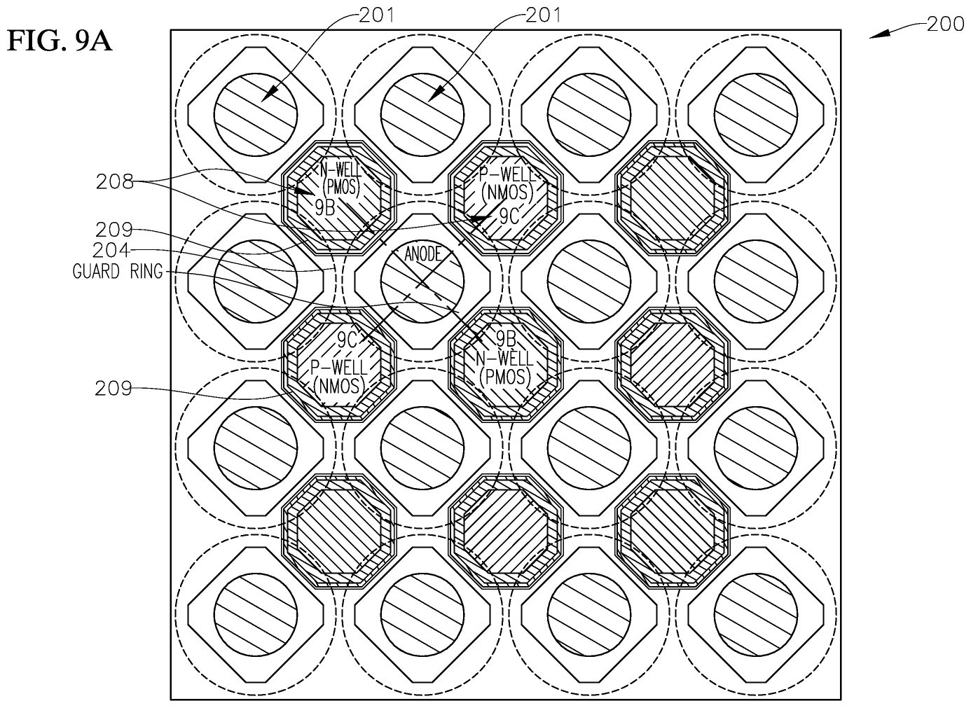

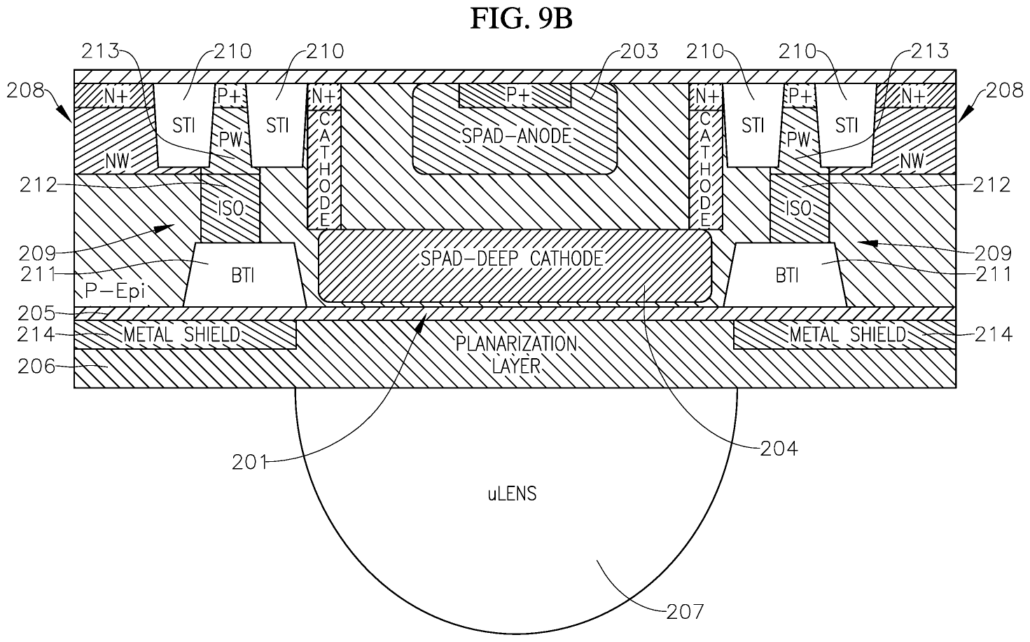

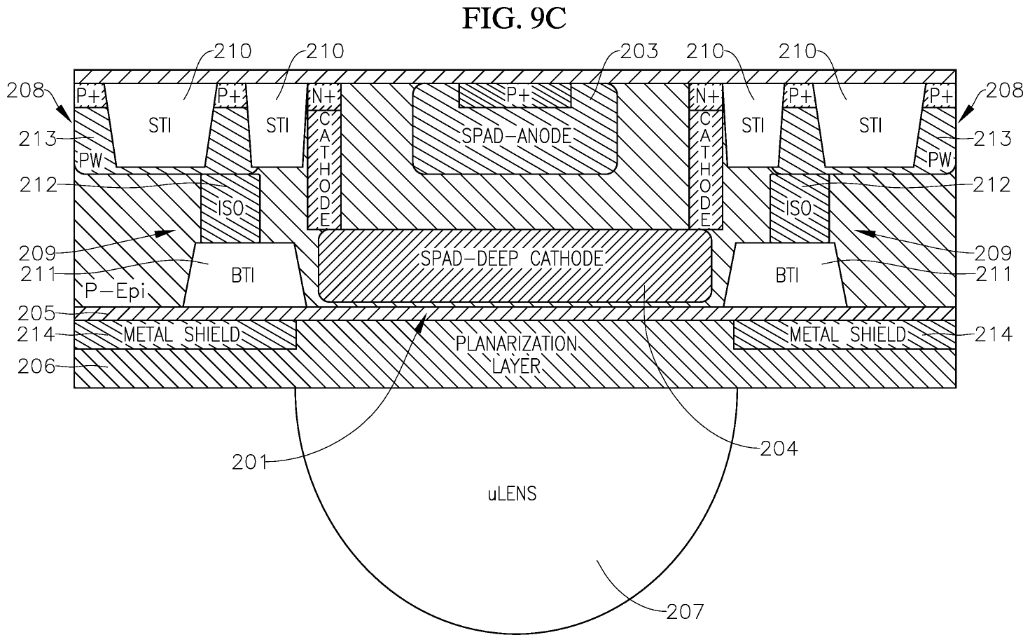

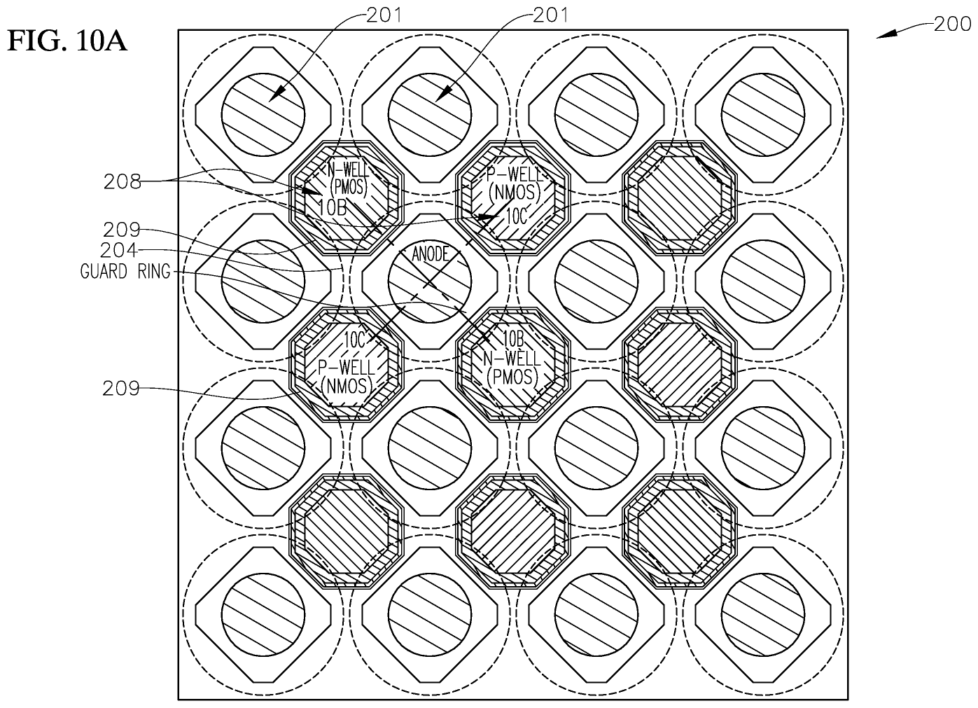

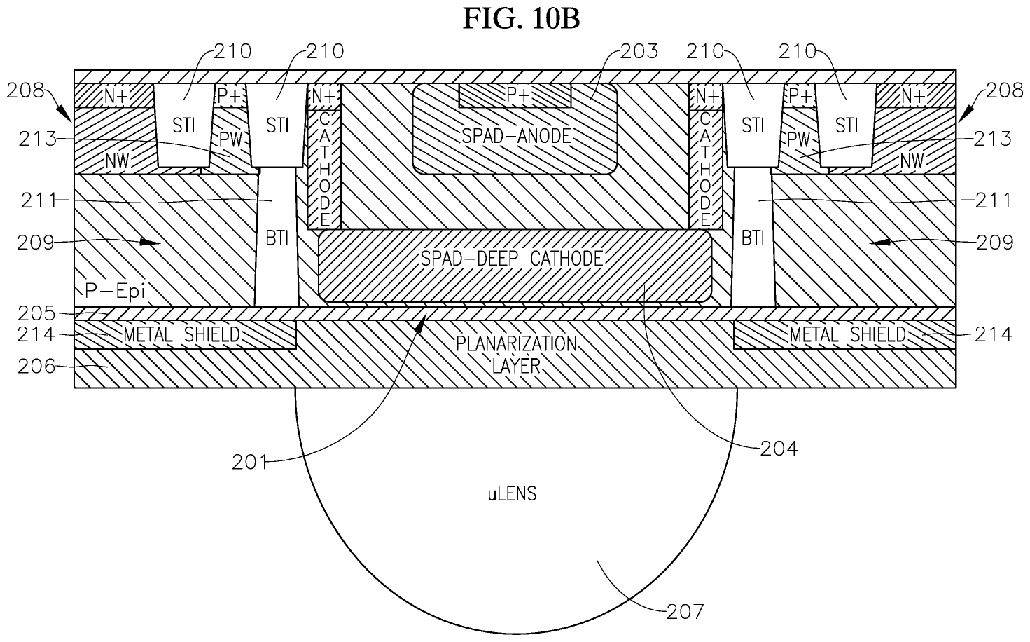

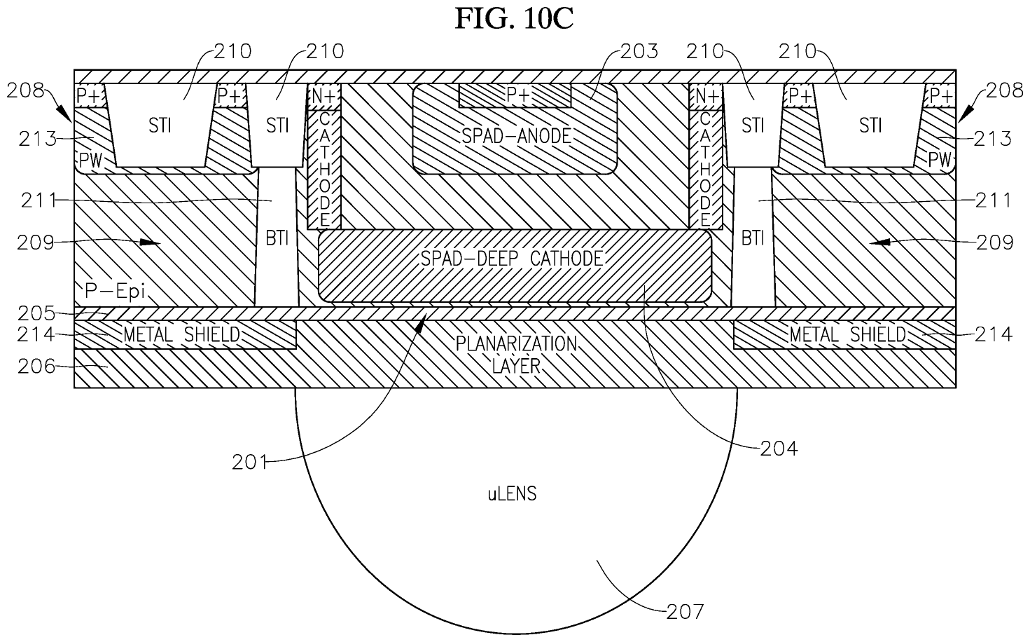

In one or more embodiments, the photodetector 200 may also include one or more isolation structures 209 configured to prevent (or at least mitigate against) current leakage between the cathodes 204 of the sensing elements 201 and the in-pixel circuitries 208. The isolation structure(s) 209 may surround the in-pixel circuitries 208 (i.e., the CMOS wells). In the embodiment illustrated in FIGS. 9A-9C, the isolation structure 209 includes a shallow-trench isolation (STI) 210 and a deep p-type isolation implant (ISO) 212. In the illustrated embodiment, the isolation structure 209 also includes a backside trench isolation (BTI) 211 extending from the dielectric stack 205 toward the STI 210, and an ISO implant 212 contacting the BTI 211 and the p-well (NMOS) 213 of the in-pixel circuitry 208 (i.e., the ISO implant 212 extends from the BTI 211 to the p-well (NMOS) 213 of the in-pixel circuitry 208). In the FIGS. 10A-10C, the isolation structure 209 includes the STI 210 and the BTI 211 contacting (i.e., directly contacting) each other. Accordingly, because the STI 210 contacts the BTI 211, the ISO implant 212 (shown in the embodiment depicted in FIGS. 9A-9C) may be omitted. In the illustrated embodiment, the photodetector 200 also includes light shielding elements 214 (e.g., a metal shield) on the dielectric stack 205 which overlaps the in-pixel circuitries 208 and (at least partially) the isolation structure 209.

While this invention has been described in detail with particular references to exemplary embodiments thereof, the exemplary embodiments described herein are not intended to be exhaustive or to limit the scope of the invention to the exact forms disclosed. Persons skilled in the art and technology to which this invention pertains will appreciate that alterations and changes in the described structures and methods of assembly and operation can be practiced without meaningfully departing from the principles, spirit, and scope of this invention, as set forth in the following claims.

What is claimed is:

1. A photodetector comprising:
a plurality of pixels, each pixel of the plurality of pixels comprising:
a plurality of photo-sensing elements;
at least one micro-lens on the plurality of photo-sensing elements; and
a refractive element between the plurality of photo-sensing elements and the at least one micro-lens,
wherein an optical center of the at least one micro-lens is offset from a center of each of the plurality of sensing elements.

2. The photodetector of claim 1, wherein a number of the at least one micro-lens is less than a number of the plurality of photo-sensing elements.

3. The photodetector of claim 1, wherein the refractive element comprises a material having a refractive index greater than 1.5.

4. The photodetector of claim 3, wherein the material of the refractive element is selected from the group consisting of SiO₂, Si₃N₄, Si, Ge, GaN, GaAs, InAs, InP, ZnS, ZnSe, ZnTe, PbTe, PbSe, PbS, Te, HfO₂, TiO₂, ZrO₂, Al₂O₃, Ta₂O₅, LiNbO₃, and a high refractive index polymer material.

5. The photodetector of claim 1, wherein the refractive element is a multi-facet prism.

6. The photodetector of claim 1, wherein the refractive element is a Fresnel prism.

7. The photodetector of claim 1, wherein the refractive element is a nanostructure prism.

8. The photodetector of claim 5, wherein a number of facets of the multi-facet prism is equal to a number of sensing elements in the pixel.

9. The photodetector of claim 8, wherein facets of the multi-facet prism are angled at at least two different angles.

10. The photodetector of claim 9, wherein an angle of a first facet of the multi-facet prism is substantially zero.

11. The photodetector of claim 1, wherein the plurality of photo-sensing elements is a plurality of single-photon avalanche diodes (SPADs).

12. The photodetector of claim 1, wherein the plurality of photo-sensing elements is a plurality of photodiodes.

13. A pixel architecture comprising:
an array of photo-sensing elements, each photo-sensing element of the plurality of photo-sensing elements comprising an anode and a cathode, wherein the cathode is shared between adjacent photo-sensing elements of the plurality of photo-sensing elements;
a plurality of CMOS elements between the array of photo-sensing elements, each of the plurality of CMOS elements comprising a p-well and an n-well;
a plurality of micro-lenses on the array of photo-sensing elements; and
at least one isolation structure separating at least one photo-sensing element of the plurality of photo-sensing elements from at least one CMOS element of the plurality of CMOS elements.

14. The pixel architecture of claim 13, wherein each of the plurality of micro-lenses is substantially symmetric, and wherein optical centers of the plurality of micro-lenses are substantially aligned with centers of the photo-sensing elements.

15. The pixel architecture of claim 13, wherein the at least one isolation structure comprises a shallow-trench isolation and an ISO implant.

16. The pixel architecture of claim 15, wherein the at least one isolation structure further comprises a backside trench isolation (BTI).

17. The pixel architecture of claim 13, wherein the at least one isolation structure comprises a backside trench isolation contacting a shallow-trench isolation.

18. The pixel architecture of claim 13, wherein the at least one isolation structure surrounds at least one CMOS element of the plurality of CMOS elements.
